(19) United States
(12) Patent Application Publication
(10) Pub. No.: US 2024/0213460 A1
(43) Pub. Date: Jun. 27, 2024

(54) LITHIUM METAL ANODE PROTECTIVE LAYER AND METHOD OF DEPOSITING SAME ON LITHIUM METAL ANODE

(71) Applicant: Belenos Clean Power Holding AG, Bienne (CH)

(72) Inventor: Jose-Antonio GONZALEZ, Lausanne (CH)

(73) Assignee: Belenos Clean Power Holding AG, Bienne (CH)

(21) Appl. No.: 18/545,314

(22) Filed: Dec. 19, 2023

Related U.S. Application Data
(60) Provisional application No. 63/435,038, filed on Dec. 23, 2022.

(51) Int. Cl. H01M 4/38; H01M 4/04; H01M 4/62; H01M 10/0525

(52) U.S. Cl. CPC H01M 4/382; H01M 4/0402; H01M 4/0471; H01M 4/62; H01M 10/0525; H01M 2004/027

(57) ABSTRACT

A lithium metal anode protective layer (a single layer or multi layers) including one or more selected from the group consisting of a halide of lithium, such as lithium iodide and lithium fluoride, a lithium metal anode including an anode active layer including lithium metal and the lithium metal anode protective layer including one or more selected from the group consisting of lithium iodide and lithium fluoride, and a method of depositing a lithium metal anode protective layer (a single layer or multi layers) on a lithium metal anode, the method including providing a coating composition including one or more selected from the group consisting of lithium iodide and lithium fluoride on the lithium metal anode, and depositing the lithium metal anode protective layer including the coating composition on the lithium metal anode by conducting a thermal evaporation.

### CROSS REFERENCE TO RELATED APPLICATIONS

This application claims priority to U.S. Provisional Application No. 63/435,038, filed on Dec. 23, 2022, the disclosure of which are incorporated by reference herein in its entirety.

### SUMMARY OF THE INVENTION

The present invention relates to a lithium metal anode protective layer comprising a halide of lithium. The metal anode protective layer of claim 1 comprising one or more layers of the halide of lithium. The halide of lithium is one or more selected from the group consisting of lithium iodide and lithium fluoride. The lithium metal anode protective layer comprises the lithium iodide and has a thickness of 5 to 800 nm. Preferably, the lithium metal anode protective layer comprises the lithium fluoride and has a thickness of about 50 to 200 nm.

### BRIEF DESCRIPTION OF THE DRAWINGS

FIG. 1 shows the lithium metal anode protective layer.

FIG. 2 shows the specific charge capacity in function of the number of charging/discharging cycles for the reference battery 20 and the first inventive battery 21 (800 nm LiI layer).

FIG. 3 shows the specific charge capacity in function of the number of charging/discharging cycles for the reference battery 20 and the second battery 22, wherein both are stable for at least 200 charging/discharging cycles.

### DETAILED DESCRIPTION OF THE INVENTION

The present disclosure provides a lithium metal anode protective layer (a single layer or multi layers) comprising one or more selected from the group consisting of a halide of lithium, such as lithium iodide and lithium fluoride. In one embodiment, the lithium metal anode protective layer comprises the lithium iodide and has a thickness of 5 to 800 nm (about 5 to about 800 nm). In another embodiment, the lithium metal anode protective layer comprises the lithium fluoride and has a thickness of about 50 to 200 nm.

In addition, the present disclosure provides a lithium metal anode comprising an anode active layer comprising lithium metal and the lithium metal anode protective layer of the present disclosure.

Moreover, the present disclosure provides a lithium ion secondary battery comprising the lithium metal anode of the present disclosure.

The present disclosure further provides a method of depositing a lithium metal anode protective layer (a single layer or multi layers) on a lithium metal anode, the method comprising providing a coating composition comprising a halide of lithium, such as one or more selected from the group consisting of lithium iodide and lithium fluoride on the lithium metal anode and depositing the lithium metal anode protective layer comprising the coating composition on the lithium metal anode by conducting a thermal evaporation. In one embodiment, the coating composition comprises the lithium iodide and the thermal evaporation that is conducted at a temperature range between 250 to 400° C., or a temperature of about 350° C. In another embodiment, the depositing is repeated for about 10 to 20 times. In some embodiment, the depositing is repeated for about 10 to 20 times to deposit the lithium metal anode protective layer in a thickness of about 300 nm.

As used herein, the term “about” means that the amount or value in question can be the exact value or a value that provides equivalent results or effects as recited in the claims or taught herein. That is, it is understood that the temperature, thickness and number are not and need not be exact, but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In such cases, it is generally understood, as used herein, that “about” means the nominal value indicated ±20% variation unless otherwise indicated or inferred.

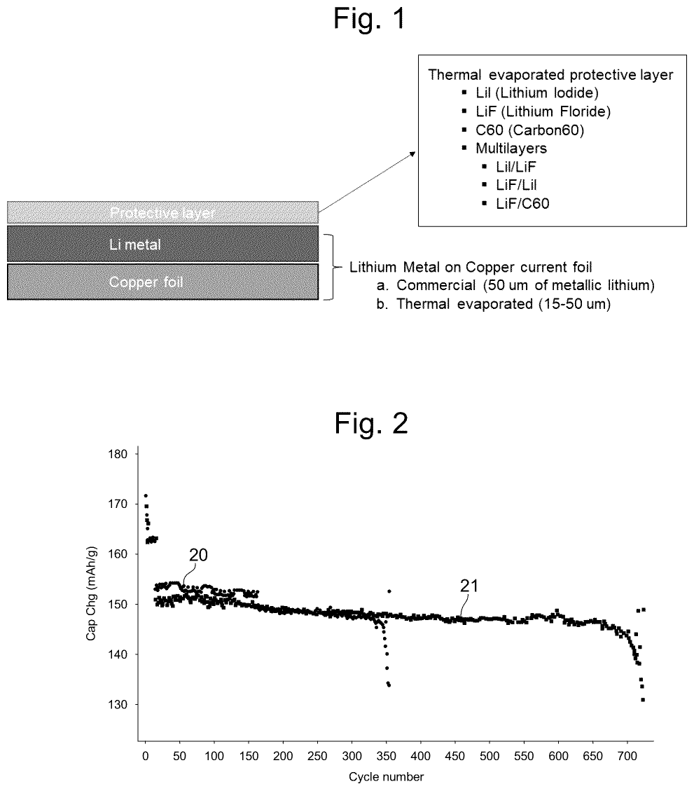

Protective layer, artificial surface electrode interface (a-SEI)) on metallic lithium are deposited to protect the lithium against the growth of dendrites when used as anode in a Li-ion battery. The concepts and the protective layers that have explored are summarized in FIG. 1 and detailed listed in Table 1, below.

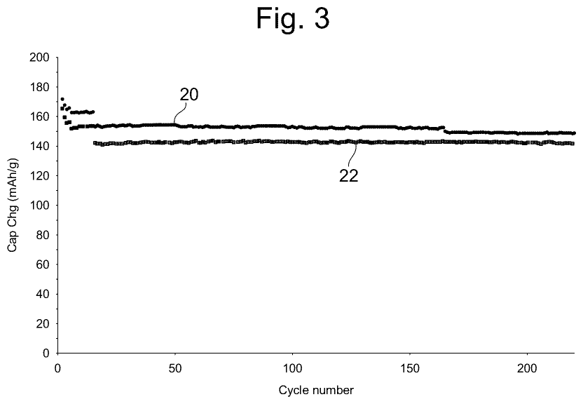

The field of study/parameters that have been tested can be summarized as:
1) Substrate:
   Commercial Lithium on Copper foil
   Thermal evaporated Lithium (10-100 nm) on copper foil
2) Nature of coating:
   a. Monolayers
      LiI (Lithium Iodide)
      LiF (Lithium Fluoride)
      C60/Carbon60
   b. Multilayers
      LiI/LiF
      LiF/LiI
3) Thickness:
   Deposition rate
   Time
   Temperature
4) Electrochemistry:
   Battery Full cell testing:
      Anode (50 μm Al_{0.3})
         Control Lithium (without protective coating)
         Lithium with coatings
      Cathodes
         Vanadate (H2V3O8) (or the cathode can be any one known in the art)
         LiFePO4 (LFP)(FIGS. 2 and 3)
      Electrolytes
         Liquid based ether electrolyte (2.36 M LIFSI in DME (dimethoxyethane))

In particular, the anode was a lithium layer on Cu. The lithium layer has impurities having native layers comprising carbonates and hydroxides. The carbonates and the oxides were not removed before the protective layers were applied. The protective layer C60 was deposited at a temperature range between 250 to 700° C. (or at a temperature of about 600 degree C.), LiF was deposited at a temperature range between 500 to 900° C. (or at a temperature of about 800 degree C.), or LiI was deposited at a temperature range between 250 to 400° C. (or at a temperature of about 350 degree C.) were deposited on the lithium layer using thermal evaporation. Thermal evaporation of C60, LiF, or LiI were achieved by placing the materials on a crucible under high vacuum.

### LiI Layer on Li-Metal

A first anode was prepared by depositing a layer of lithium iodide (LiI) on an anode active substrate that was commercially purchased and consisted of a 13 μm thick copper foil as current collector with a 50 μm thick layer of lithium metal and a native layer of Li2CO3. The deposition was performed by depositing a coating composition substantially consisting of lithium iodide (LiI) on the lithium metal layer by means of thermal evaporation at 350° C. in a processing chamber operating at ultra-high vacuum (UHV). A thermal evaporation source (i.e. coating composition) containing LiI was used. The deposition step was repeated 20 times, thereby obtaining a LiI layer having a thickness of 800 nm.

### LiI on LiF

A second anode was prepared, again in UHV conditions, by depositing first a layer of LiF on the same copper foil with a 50 μm thick layer of lithium metal, followed by deposition of a layer of LiI. The LiF layer was deposited on the lithium metal layer by thermal evaporation at 800° C. A thermal evaporation source containing LiF was used. The depositions were repeated until the LiF layer had a thickness of 200 nm. The LiI layer was deposited on the LiF layer by thermal evaporation at 350° C. using a thermal evaporation source containing LiI. The depositions were repeated until a the LiI layer had a thickness of 800 nm. Both depositions were performed in the same processing chamber without breaking the UHV in order to prevent any possible contamination between the subsequent depositions.

Next, first and second inventive lithium ion batteries were prepared, comprising the first and second anodes of the invention. A LiFePO4 (LFP) cathode was used, and the electrolyte was 2 M LiFSI in an ether based electrolyte.

A reference lithium ion battery was prepared as well, having the same cathode and electrolyte as the first and second inventive lithium ion batteries, but the commercial anode active substrate (13 μm thick copper foil as current collector with a 50 μm thick layer of lithium metal and a native layer of Li2CO3) without any further treatment as anode.

The batteries were then repeatedly charged and discharged. Charging was performed at 4.3 mA until 3.8 V was reached. Discharging was performed at ca. 10 mA until 2.2 V was reached.

FIG. 2 shows the specific charge capacity in function of the number of charging/discharging cycles for the reference battery 20 and the first inventive battery 21 (800 nm LiI layer). It is clear that the reference battery shows a clear decrease in performance after 340 charging/discharging cycles, whereas the first inventive battery remains stable for almost 700 cycles.

FIG. 3 shows the specific charge capacity in function of the number of charging/discharging cycles for the reference battery 20 and the second battery 22, wherein both are stable for at least 200 charging/discharging cycles

In summary, the depositions offering good results in terms of homogeneity, surface roughness, degradation and electrochemical performances were obtained using LiI that was thermo-evaporated at around 350° C. and the deposition was repeated ten times to achieve a thickness estimated to 800 nm. The electrochemistry performance of the best sample against a control is showed in FIG. 2.

The depositions also offering the good results in terms of homogeneity, surface roughness, degradation and electrochemical performances were obtained using a multilayer or in particular bi-layer of LiF and LiI wherein LiF and LiI were thermally evaporated. LiI was evaporated for single layer and multilayer at around 350° C. The electrochemistry performance of the best sample against a control is showed in FIG. 3.

Such multilayer protective layer is between 5 nm to 1.5 microns.

The exact role of the LiI is still under investigation, several scientific papers claiming a “healing effect” of LiI due to the I⁻/I₃⁻ redox couple and the fact that if Li dendrites are formed can react with iodine and form LiI, dissolving the dendrite and preventing cell shorting, and recovering from dendrite formation.

TABLE 1
Coatings performed

| Sample | COATINGS | REMARKS |
|---|---|---|
| 1-2 | C60 (5, 50 nm) | Sample 1: 5 nm of C60 |
| | | Sample 2: 50 nm of C60 |
| 3-6 | LiI (5, 50, 100, 800 nm) | Sample 3: 5 nm of LiI |
| | | Sample 4: 50 nm of LiI |
| | | Sample 5: 100 nm of LiI |
| | | Sample 6: 800 nm of LiI |
| 7-9 | LiF (5, 50, 100, 200 nm) | Sample 7: 5 nm of LiF |
| | | Sample 8: 100 nm of LiF |
| | | Sample 9: 200 nm of LiF |
| 10-11 | Li-F 50 nm + C60 50 nm | Sample 10: 50 nm of LiF is |
| | Li-F 200 nm + C60 50 nm | deposited immediately on top of |
| | | Li-metal and a 50 nm of C60 is |
| | | subsequently deposited on top |
| | | of LiF |
| | | Sample 11: 200 nm of LiF is |
| | | deposited immediately on top of |
| | | Li-metal and a 50 nm of C60 is |
| | | on top of LiF |

1. A lithium metal anode protective layer comprising a halide of lithium.

2. The lithium metal anode protective layer of claim 1 comprising one or more layers of the halide of lithium.

3. The lithium metal anode protective layer of claim 1, wherein the halide of lithium is one or more selected from the group consisting of lithium iodide and lithium fluoride.

4. The lithium metal anode protective layer of claim 2, wherein the halide of lithium is one or more selected from the group consisting of lithium iodide and lithium fluoride.

5. The lithium metal anode protective layer of claim 1, wherein the lithium metal anode protective layer comprises the lithium iodide and has a thickness of 5 to 800 nm.

6. The lithium metal anode protective layer of claim 1, wherein the lithium metal anode protective layer comprises the lithium fluoride and has a thickness of about 50 to 200 nm.

7. A lithium metal anode, comprising:
an anode active layer comprising lithium metal; and
the lithium metal anode protective layer according to claim 1 provided on the anode active layer.

8. A lithium metal anode, comprising:
an anode active layer comprising lithium metal; and
the lithium metal anode protective layer according to claim 5 provided on the anode active layer.

9. A lithium metal anode, comprising:
an anode active layer comprising lithium metal; and
the lithium metal anode protective layer according to claim 6 provided on the anode active layer.

10. A lithium ion secondary battery comprising the lithium metal anode according to claim 7.

11. A lithium ion secondary battery comprising the lithium metal anode according to claim 8.

12. A lithium ion secondary battery comprising the lithium metal anode according to claim 9.

13. A method of depositing a lithium metal anode protective layer on a lithium metal anode, the method comprising:
providing a coating composition comprising a halide of lithium on the lithium metal anode; and
depositing the lithium metal anode protective layer comprising the coating composition on the lithium metal anode by conducting a thermal evaporation.

14. The method of claim 13, wherein the providing the coating composition comprises providing one or more layers of coating composition comprising one or more selected from the group consisting of lithium iodide and lithium fluoride on the lithium metal anode.

15. The method of claim 13, wherein the coating composition comprises the lithium iodide and the thermal evaporation is conducted at a temperature of about 350° C.

16. The method of claim 14, wherein the coating composition comprises the lithium iodide and the thermal evaporation is conducted at a temperature of about 350° C.

17. The method of claim 13, wherein the depositing is repeated for about 10 to 20 times.

18. The method of claim 14, wherein the depositing is repeated for about 10 to 20 times.

19. The method of claim 13, wherein the depositing is repeated for about 10 to 20 times to deposit the lithium metal anode protective layer in a thickness of about 800 nm.

20. The method of claim 14, wherein the depositing is repeated for about 10 to 20 times to deposit the lithium metal anode protective layer in a thickness of about 800 nm.
